(19) United States
(12) Patent Application Publication
(10) Pub. No.: US 2019/0221483 A1
(43) Pub. Date: Jul. 18, 2019

(54) SINGLE WORK FUNCTION ENABLEMENT FOR SILICON NANOWIRE DEVICE

(71) Applicant: GLOBALFOUNDRIES INC., GRAND CAYMAN (KY)

(72) Inventors: George MULFINGER, Gansevoort, NY (US); Scott BEASOR, Greenwich, NY (US); Timothy MCARDLE, Ballston Lake, NY (US)

(73) Assignee: GLOBALFOUNDRIES INC., GRAND CAYMAN (KY)

(21) Appl. No.: 15/869,325

(22) Filed: Jan. 12, 2018

(51) Int. Cl. H01L 21/8238; H01L 21/28

(52) U.S. Cl. CPC H01L 21/823807; H01L 21/823821; H01L 29/7853; H01L 21/28088; H01L 21/28255; H01L 21/823814

(57) ABSTRACT

A method of forming nanosheet and nanowire transistors includes the formation of alternating epitaxial layers of silicon germanium (SiGe) and silicon (Si). The silicon germanium layers include etch-selective high-germanium content silicon germanium layers and low-germanium content silicon germanium layers. Single work function metal PFET and NFET devices can be formed on the same substrate by incorporating the low-germanium content silicon germanium layers into the channel region within p-type device regions, whereas both the high-germanium content silicon germanium layers and the low-germanium content silicon germanium layers are removed from within n-type device regions.

### BACKGROUND

The present application relates generally to semiconductor devices, and more specifically to vertically-stacked nanosheet or nanowire transistors and their methods of production.

A nanosheet or a nanowire field effect transistor (FET) includes plural layers of nano-dimensional semiconductor material that function as the channel regions of the device. Such nanosheet- or nanowire-based structures enable feature scaling beyond current two-dimensional CMOS technology.

At advanced nodes, however, conventional fabrication methods that use alternating sacrificial layers to offset the active nanostructures with respect to one another, as well as template their growth, may present geometries that challenge the removal of the sacrificial layers as well as the subsequent formation of complete work functional metal stacks between neighboring active layers.

### SUMMARY

Notwithstanding recent developments, there is a need for improved manufacturing methods for nanostructure devices, including nanosheet- and nanowire-based transistors. In accordance with embodiments of the present application, PFET and NFET nanostructure transistors can be formed by simultaneously depositing the same work function metal stack for each device. Independent work functions for the PFET and NFET devices can be attained by incorporating a low-germanium content silicon germanium (SiGe) epitaxial layer into the functional gate of the PFET device.

An example method of forming PFET and NFET devices on a common substrate includes forming a stack of epitaxial layers over a semiconductor substrate wherein the stack includes, from bottom to top, a first layer of high-germanium content silicon germanium, a first layer of low-germanium content silicon germanium, a first layer of silicon, a second layer of low-germanium content silicon germanium and a second layer of high-germanium content silicon germanium. The stack, which may be repeated to form multiple nanowires or nanosheets, is patterned to form a first fin within a first (e.g., PFET) device region and a second fin within a second (e.g., NFET) device region.

The first layer of high-germanium content silicon germanium and the second layer of high-germanium content silicon germanium are then removed from within the first device region, and the first layer of high-germanium content silicon germanium, the second layer of high-germanium content silicon germanium, the first layer of low-germanium content silicon germanium and the second layer of low-germanium content silicon germanium are removed from within the second device region.

The method further includes forming the same work function metal layer within the first and second device regions, wherein the work function metal layer is formed directly over the first and second low-germanium content silicon germanium layers within the first device region, and directly over the first layer of silicon within the second device region.

A further method includes forming a stack of epitaxial layers over a semiconductor substrate, wherein the stack includes, from bottom to top, a first layer of high-germanium content silicon germanium formed directly over the semiconductor substrate, a first layer of low-germanium content silicon germanium, a first layer of silicon, a second layer of low-germanium content silicon germanium and a second layer of high-germanium content silicon germanium.

The stack is patterned to form a first fin within a first device region and a second fin within a second device region. The first layer of high-germanium content silicon germanium and the second layer of high-germanium content silicon germanium are then removed from within the first and second device regions, and thereafter a masking layer is formed over the first device region.

The method further includes removing the first layer of low-germanium content silicon germanium and the second layer of low-germanium content silicon germanium from within the second device region, and forming a work function metal layer within the first and second device regions, wherein the work function metal layer is formed directly over the first and second low-germanium content silicon germanium layers within the first device region, and directly over the first layer of silicon within the second device region.

### BRIEF DESCRIPTION OF SEVERAL VIEWS OF THE DRAWINGS

The following detailed description of specific embodiments of the present application can be best understood when read in conjunction with the following drawings, where like structure is indicated with like reference numerals and in which:

FIG. 1 is a schematic cross-sectional diagram according to various embodiments showing a stack of epitaxial layers formed over a semiconductor substrate;

FIG. 2 shows patterned epitaxial layers, the formation of shallow trench isolation between p-type and n-type device regions, the deposition of inner spacers over laterally-recessed portions of the epitaxial layers, and the formation of source/drain regions over the inner spacers and over endwalls of silicon epitaxial layers;

FIG. 2A is a transverse cross-sectional view of the structure of FIG. 2 through the epitaxial layers within an n-type device region showing the patterned stack of epitaxial layers and an overlying sacrificial gate;

FIG. 3 shows the formation of an interlayer dielectric over the source/drain regions and the selective removal of the sacrificial gate to expose the epitaxial layers within each device region;

FIG. 3A is a transverse cross-sectional view of the structure of FIG. 3 through the epitaxial layers within the n-type device region following removal of the sacrificial gate;

FIG. 4 shows selective removal of high-germanium content silicon germanium epitaxial layers to expose the low-germanium content silicon germanium epitaxial layers and the silicon epitaxial layers within the p-type and n-type device regions;

FIG. 4A is a transverse cross-sectional view of the structure of FIG. 4 within the n-type device region showing the revealed epitaxial layers;

FIG. 5 shows the deposition of a block mask within the p-type device region and the subsequent selective removal of the low-germanium content silicon germanium epitaxial layers from within the n-type device region;

FIG. 5A is a transverse cross-sectional view of the structure of FIG. 5 within the n-type device region following removal of the low-germanium content silicon germanium epitaxial layers showing the revealed silicon nanostructures;

FIG. 6 shows the deposition of a work function metal layer stack within the p-type and n-type device regions;

FIG. 6A is a transverse cross-sectional view of the structure of FIG. 6 within the n-type device region showing the work function metal layer stack formed directly over the silicon nanostructures; and

FIG. 6B is a transverse cross-sectional view of the structure of FIG. 6 within the p-type device region showing the work function metal layer stack formed directly over the low-germanium content silicon germanium epitaxial layers.

### DETAILED DESCRIPTION

Reference will now be made in greater detail to various embodiments of the subject matter of the present application, some embodiments of which are illustrated in the accompanying drawings. The same reference numerals will be used throughout the drawings to refer to the same or similar parts.

Disclosed are methods for forming a nanosheet or nanowire field effect transistor as well as a resulting nanostructure device. Gate-all-around (GAA) nanostructure channel transistors such as nanosheet and nanowire FETs enable feature scaling beyond current two-dimensional CMOS technology. Such devices include source and drain regions, and stacked nanostructured channel regions disposed therebetween. In various embodiments, a functional gate, including a gate dielectric and a gate conductor, which includes one or more work function metal layers, surrounds the stacked nano-dimensional channels and controls electron flow through the channels between the source and drain regions. A “functional gate” is operable to switch the semiconductor device from an “on” state to “off” state, and vice versa.

Nanosheet and nanowire devices can be formed from alternating epitaxial layers of an active semiconductor material such as silicon (Si), using sacrificial semiconductor material layers such as silicon germanium (SiGe) layers as templates for epitaxial growth and as interlayer spacers that define a distance between adjacent nanowires or nanosheets. However, the three-dimensional geometry associated with closely-spaced active channel layers can challenge the ability to deposit a complete functional gate within the available space between such layers, which may lead to inferior manufacturability, yield and/or performance.

Accordingly, the present disclosure provides fabrication methodologies and resulting devices for stacked nanosheet and nanowire transistors having improved manufacturability. In various embodiments, the disclosed methods enable the co-integration of single work function metal PFET and NFET devices on the same substrate.

As used herein, a “nanowire” device is characterized by a channel having a critical dimension (CD) of less than 30 nm, while a “nanosheet” device is characterized by a channel having a critical dimension of 30 nm or greater. In exemplary devices, the critical dimension is measured along the gate. In that direction, if the width of the GAA channel is small, the channel cross-section is like a “wire” whereas if the width of the GAA channel is large, the channel cross-section is like a “sheet.” As will be appreciated, the presently disclosed methods may be incorporated into the manufacture of nanowire as well as nanosheet devices.

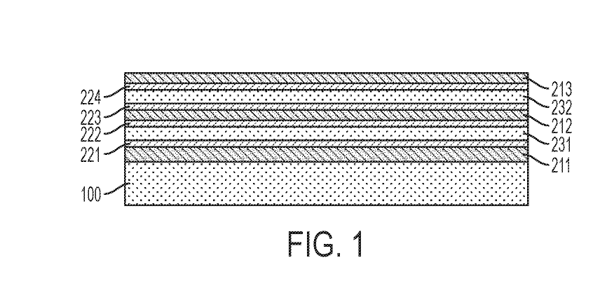

An exemplary process flow for forming a nanowire or nanosheet device is described herein with reference to FIGS. 1-6. As shown in FIG. 1, epitaxial silicon germanium layers 211, 212, 213, 221, 222, 223, 224 and epitaxial silicon layers 231, 232 are sequentially formed as a planar stack over a substrate 100. As will be appreciated, the silicon germanium layers may be sacrificial layers, e.g., within an NFET device region, while a sub-set of the silicon germanium layers may be incorporated into a final device architecture, e.g., within a PFET device.

The substrate 100 may include a semiconductor material such as silicon, e.g., single crystal Si or polycrystalline Si, or a silicon-containing material. Silicon-containing materials include, but are not limited to, single crystal silicon germanium (SiGe), polycrystalline silicon germanium, silicon doped with carbon (Si:C), amorphous Si, as well as combinations and multi-layers thereof. As used herein, the term “single crystal” denotes a crystalline solid, in which the crystal lattice of the entire solid is substantially continuous and substantially unbroken to the edges of the solid with substantially no grain boundaries.

The substrate 100 is not limited to silicon-containing materials, however, as the substrate 100 may include other semiconductor materials, including Ge and compound semiconductors, including III-V compound semiconductors such as GaAs, InAs, GaN, GaP, InSb, ZnSe, and ZnS, and II-VI compound semiconductors such as CdSe, CdS, CdTe, ZnSe, ZnS and ZnTe.

Substrate 100 may be a bulk substrate or a composite substrate such as a semiconductor-on-insulator (SOI) substrate that includes, from bottom to top, a handle portion, an isolation layer (e.g., buried oxide layer), and a semiconductor material layer.

Substrate 100 may have dimensions as typically used in the art and may include, for example, a semiconductor wafer. Example wafer diameters include, but are not limited to, 50, 100, 150, 200, 300 and 450 mm. The total substrate thickness may range from 250 microns to 1500 microns, although in particular embodiments the substrate thickness is in the range of 725 to 775 microns, which corresponds to thickness dimensions commonly used in silicon CMOS processing. The substrate 100 may include (100)-oriented silicon or (111)-oriented silicon, for example. In example embodiments, the as-deposited semiconductor layers are undoped.

As illustrated in FIG. 1, the planar stack of epitaxial layers is configured such that a high-germanium content silicon germanium layer 211 is deposited directly over a top surface of the substrate 100, a low-germanium content silicon germanium layer 221 is deposited directly over the high-germanium content silicon germanium layer 211, a silicon layer 231 is deposited directly over the low-germanium content silicon germanium layer 221, and a low-germanium content silicon germanium layer 222 is deposited directly over the silicon layer 231. To create multiple stacked nanowire or nanosheets, the foregoing sequence of epitaxial layers can be repeated, such that each silicon layer is sandwiched directly between an underlying and an overlying low-germanium content silicon germanium layer.

As used herein, a “low-germanium content” silicon germanium layer may include 15 to 25 atomic percent germanium, e.g., 15, 20 or 25 at. %, including ranges between any of the foregoing values. According to various embodiments, the low-germanium content silicon germanium layers may be retained within a portion of the final device architecture, e.g., within p-type device regions as a layer disposed between the channel and the gate that modifies the work function of the device, whereas the low-germanium content silicon germanium layers may be removed from within other portions of the final device architecture, e.g., n-type device regions. Thus, the low-germanium content silicon germanium epitaxial layers are adapted to function as a PFET work function layer. According to various embodiments, the low-germanium content silicon germanium epitaxial layers 221, 222, 223, 224 are adapted to conduct current and therefore form part of the channel of a PFET device, but also serve to modify the work function of the PFET device. By way of example, retention of a 20 at. % silicon germanium layer within a PFET device around a silicon channel may induce a 300 mV shift in the work function.

A “high-germanium content” silicon germanium layer, on the other hand, may include 30 to 50 atomic percent germanium, e.g., 30, 35, 40, 45 or 50 at. %, including ranges between any of the foregoing values. According to various embodiments, the high-germanium content silicon germanium layers are sacrificial layers, and are therefore removed from both p-type and n-type device regions, e.g., to create openings for the GAA architecture.

In certain embodiments, the high- and low-germanium content silicon germanium layers are adapted to be etch selective with respect to each other. In various methods the difference in the germanium concentration between the high-germanium content silicon germanium layers and the low-germanium content silicon germanium layers is such that the high-germanium content silicon germanium layers can be removed selective to the low-germanium content silicon germanium layers. For example, a difference in the germanium content between the high-germanium content silicon germanium layers and the low-germanium content silicon germanium layers may be at least 15 atomic percent, e.g., 15, 20 or 25 at. %, including ranges between any of the foregoing values.

The thickness of each epitaxial layer is not particularly limited, although in certain embodiments the high-germanium content silicon germanium layers 211, 212, 213 each have a thickness of 2 to 4 nm, the low-germanium content silicon germanium layers 221, 222, 223, 224 each have a thickness of 3 to 5 nm, and the silicon epitaxial layers 231, 232 each have a thickness of 4 to 6 nm.

In various embodiments, the epitaxial stack initiates and terminates with a high-germanium content silicon germanium layer. For simplicity of illustration, a pair of silicon epitaxial layer 231, 232 is shown in FIG. 1 with under- and over-lying silicon germanium layers. However, fewer or greater semiconductor layers and/or sacrificial (SiGe) layers may be formed by epitaxial growth in an alternating fashion over substrate 100.

The terms “epitaxy,” “epitaxial” and/or “epitaxial growth and/or deposition” refer to the formation of a semiconductor material layer on a deposition surface of a semiconductor material, in which the semiconductor material layer being grown assumes the same crystalline habit as the semiconductor material of the deposition surface. For example, in an epitaxial deposition process, chemical reactants provided by source gases are controlled and the system parameters are set so that depositing atoms alight on the deposition surface and remain sufficiently mobile via surface diffusion to orient themselves according to the crystalline orientation of the atoms of the deposition surface. Therefore, an epitaxial semiconductor material will adopt the same crystalline characteristics as the deposition surface on which it is formed. For example, an epitaxial semiconductor material deposited on a (100) crystal surface will take on a (100) orientation.

As will be appreciated, the silicon germanium layers serve as sacrificial spacer layers that offset the epitaxial silicon layers 231, 232 from each other. The silicon germanium layers also serve as template layers upon which the silicon layers can be grown epitaxially.

Epitaxial layers (i.e., the silicon germanium and silicon layers) may be formed by a reduced pressure molecular beam epitaxy (MBE) or a chemical vapor deposition (CVD) process, for example, at a substrate temperature of 450-700° C. and a growth pressure (i.e., chamber pressure) of 0.1-700 Torr. A source of silicon may be silane gas (SiH₄), and a germanium source for the SiGeₓ epitaxy may be germane gas (GeH₄). Hydrogen may be used as a carrier gas.

According to various embodiments, a first high-germanium content silicon germanium layer 211 is epitaxially grown on substrate 100, and a first low-germanium content silicon germanium layer 221 is epitaxially grown on the first high-germanium content silicon germanium layer 211. During an exemplary process, a silicon precursor (e.g., silane) flows concurrently into a process chamber with a carrier gas (e.g., H₂ and/or N₂) and a germanium source (e.g., GeH₄ or GeCl₄). By way of example, the flow rate of the silicon source may be in the range of 5 sccm to 500 sccm, the flow rate of the germanium source may be in the range of 0.1 sccm to 10 sccm, and the flow rate of the carrier gas may be in the range of 1,000 sccm to 60,000 sccm, although lesser and greater flow rates may be used.

As will be appreciated, other suitable gas sources for silicon include silicon tetrachloride (SiCl₄), dichlorosilane (SiH₂Cl₂), trichlorosilane (SiHCl₃), and other hydrogen-reduced chlorosilanes (SiHxCl₄₋ₓ). In lieu of germane, other germanium sources or precursors may be used to form epitaxial silicon germanium layers. Higher germanes include the compounds with the empirical formula GeₓH₍₂ₓ₊₂₎, such as digermane (Ge₂H₆), trigermane (Ge₃H₈) and tetragermane (Ge₄H₁₀), as well as others. Organogermanes include compounds with the empirical formula R_{y}GeₓH_{(2x+2-y)}, where R=methyl, ethyl, propyl or butyl, such as methylgermane ((CH₃)GeH₃), dimethylgermane ((CH₃)₂GeH₂), ethylgermane ((CH₃CH₂)GeH₃), methyldigermane ((CH₃)Ge₂H₅), dimethyldigermane ((CH₃)₂Ge₂H₄) and hexamethyldigermane ((CH₃)₆Ge₂).

The process chamber may be maintained at a pressure of 0.1 Torr to 700 Torr, while the substrate 100 is maintained at a temperature in the range of 450° C. to 700° C. The process according to certain embodiments is conducted to form a first high-germanium content silicon germanium layer 211 having a thickness in a range of 2 to 4 nm and a first low-germanium content silicon germanium layer 221 having a thickness in a range from 3 to 5 nm. During the formation of each silicon germanium layer, e.g., silicon germanium layers 211, 221, the flow rate and/or the partial pressure of the silicon source and the germanium source can be varied to form SiGe layers having a high-germanium content or a low-germanium content, as described above.

Following deposition of the first high-germanium content silicon germanium layer 211 and the first low-germanium content silicon germanium layer 221, a first epitaxial silicon layer 231 is formed directly over the first low-germanium content silicon germanium layer 221. According to an example method, during deposition of the first silicon layer 231, a silicon precursor (e.g., silane) is flown concurrently into the process chamber with a carrier gas (e.g., H₂ and/or N₂). The flow rate of the silane may be in the range of 5 sccm to 500 sccm, and the flow rate of the carrier gas may be in the range of 1,000 sccm to 60,000 sccm, although lesser and greater flow rates may be used.

The process chamber for deposition of the first silicon layer 231 may be maintained at a pressure of 0.1 Torr to 700 Torr, while the substrate 100 is maintained at a temperature in the range of 450° C. to 700° C. The process according to certain embodiments is conducted to form a first silicon layer 231 with a thickness in a range from 4 to 6 nm.

Following deposition of the first high-germanium silicon germanium layer 211, the first low-germanium silicon germanium layer 221, and the first silicon layer 231, according to the illustrated embodiment, silicon germanium and silicon epitaxial process conditions are used to deposit a second low-germanium silicon germanium layer 222 directly over the first silicon layer 231, a second high-germanium silicon germanium layer 212 directly over the second low-germanium silicon germanium layer 222, a third low-germanium silicon germanium layer 223 directly over the second high-germanium silicon germanium layer 212, a second silicon layer 232 directly over the third low-germanium silicon germanium layer 223, a fourth low-germanium silicon germanium layer 224 directly over the second silicon layer 232, and a third high-germanium silicon germanium layer 213 directly over the fourth low-germanium silicon germanium layer 224.

In various embodiments, the thickness and composition amongst the respective high- and low-germanium content SiGe layers and amongst the silicon layers may be constant, while the high- and low-germanium content SiGe layers are thinner than the silicon layers. In various embodiments, the thickness amongst the respective high- and low-germanium content SiGe layers and amongst the silicon semiconductor layers may be constant, while the high-germanium content SiGe layers are thinner than the low-germanium content SiGe layers.

Conventional patterning and etching techniques may be used to pattern the planar stack into a three-dimensional structure, e.g., fin, which enables later-formed gates to wrap around the epitaxial layers.

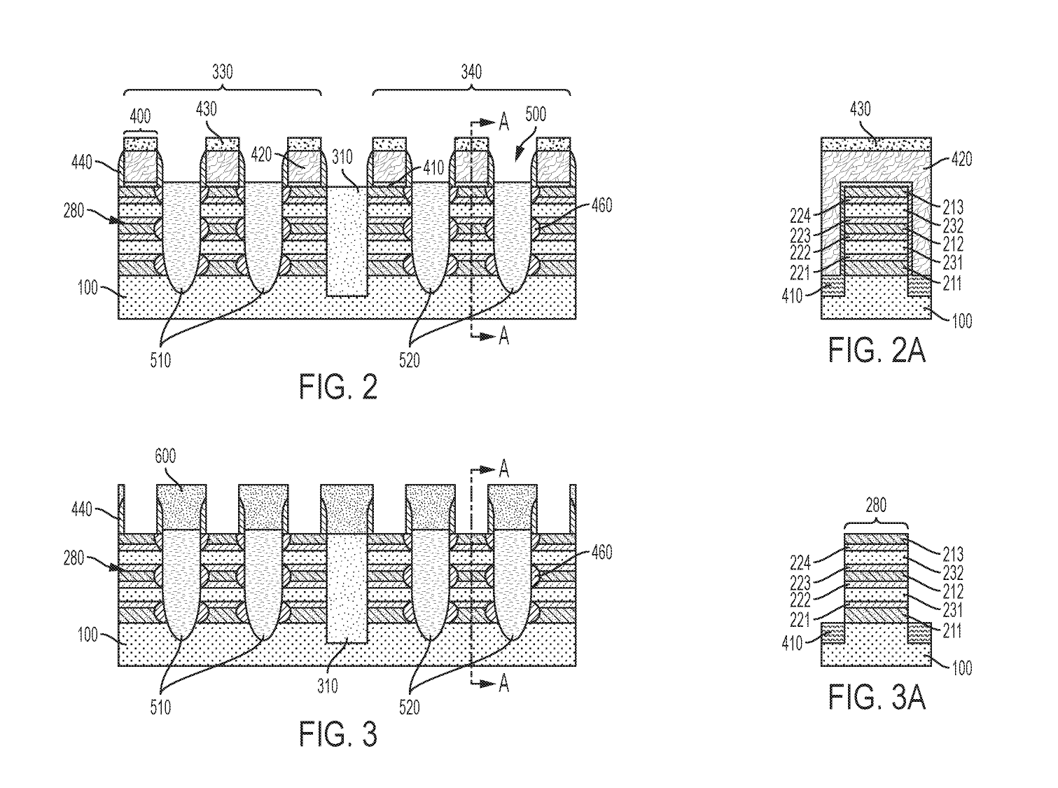

Referring to FIG. 2, a shallow trench isolation (STI) layer 310 may be used to provide electrical isolation between adjacent device regions as is needed for the circuit(s) being implemented. Example adjacent device regions may include a PFET region 330 and an NFET region 340.

An example STI process involves creating isolation trenches through the epitaxial stack and into the substrate 100 using an anisotropic etch process. The isolation trench between device regions may have a relatively high aspect ratio (e.g., ratio of the depth of the isolation trench to its width). A dielectric fill material, such as silicon dioxide, is deposited into the isolation trenches, for example, using an enhanced high aspect ratio process (eHARP) to fill the isolation trenches. The deposited dielectric material may then be polished by a chemical-mechanical polishing (CMP) process that removes the excess dielectric material and creates a planar STI structure.

A sacrificial gate 400 is then formed over the patterned stack of epitaxial layers, and sidewall spacers 440 are formed over sidewalls of the sacrificial gate 400. The sacrificial gate 400 may include a sacrificial gate dielectric 410, a sacrificial gate conductor 420, and a sacrificial gate cap 430. In the illustrated embodiment, the sacrificial gate dielectric 410 is formed directly over the top-most layer in the stack of epitaxial layers. The layers within the sacrificial gate 400 may be formed using, for example, chemical vapor deposition (CVD), physical vapor deposition (PVD), molecular beam deposition (MBD), pulsed laser deposition (PLD), liquid source misted chemical deposition (LSMCD), atomic layer deposition (ALD), etc.

Prior to forming the sacrificial gate 400, an oxide etch back may be used to reveal the fins. The etch back enables the sacrificial gate 400 to wrap around a three-dimensional fin structure of epitaxial layers, while retaining the isolation layer 310 beneath the sacrificial gate 400 as shown in FIG. 2A.

The sacrificial gate dielectric 410 may include a layer of silicon dioxide, and the sacrificial gate conductor 420 may include a layer of amorphous silicon (a-Si), for example. Amorphous elemental silicon can be deposited using chemical vapor deposition, such as low pressure chemical vapor deposition (LPCVD) at temperatures ranging from 450° C. to 700° C. Silane (SiH₄) can be used as the precursor for CVD silicon deposition. The sacrificial gate cap 430 may include silicon nitride. In various embodiments, the sacrificial gate 400 includes materials that can be etched selectively with respect to the sidewall spacers 440.

Patterning and etching processes known to those skilled in the art may be used to form the sacrificial gates 400 within both the PFET region 330 and the NFET region 340. For instance, the patterning process may include photolithography, which involves forming a layer of photoresist material (not shown) atop a material layer to be patterned. The photoresist may include a positive-tone photoresist composition, a negative-tone photoresist composition, or a hybrid-tone photoresist composition. A layer of photoresist may be formed by a deposition process such as, for example, spin-on coating.

The deposited photoresist is then subjected to a pattern of irradiation, and the exposed photoresist is developed utilizing a conventional resist developer. The pattern provided by the patterned photoresist is transferred into the underlying sacrificial gate cap 430 and thereafter into the sacrificial gate conductor 420 and the sacrificial gate dielectric 410 utilizing at least one pattern transfer etching process.

The pattern transfer etching process may be an isotropic or an anisotropic etch. In certain embodiments, a dry etching process such as, for example, reactive ion etching (RIE) can be used. In other embodiments, a wet chemical etchant can be used. In still further embodiments, a combination of dry etching and wet etching can be used.

Sidewall spacers 440 may be formed by blanket (conformal) deposition of a spacer material (e.g., using an atomic layer deposition process), followed by a directional (anisotropic) etch such as reactive ion etching (RIE) to remove the spacer material from horizontal surfaces. In certain embodiments, the sidewall spacer thickness is 5 to 20 nm, e.g., 5, 10, 15 or 20 nm, including ranges between any of the foregoing values.

Suitable sidewall spacer materials include oxides, nitrides and oxynitrides, such as silicon dioxide, silicon nitride, silicon oxynitride, and low dielectric constant (low-k) materials such as amorphous carbon, SiOC, SiOCN and SiBCN, as well as a low-k dielectric material. As used herein, a low-k material has a dielectric constant less than that of silicon nitride.

As will be appreciated, the compounds silicon dioxide and silicon nitride have compositions that are nominally represented as SiO₂ and Si₃N₄, respectively. The terms silicon dioxide and silicon nitride, as used herein, refer to not only these stoichiometric compositions, but also to oxide and nitride compositions that deviate from the stoichiometric compositions.

Exemplary low-k materials include but are not limited to, amorphous carbon, fluorine-doped oxides, or carbon-doped oxides. Commercially-available low-k dielectric products and materials include Dow Corning's SiLK™ and porous SiLK™, Applied Materials' Black Diamond™, Texas Instrument's Coral™ and TSMC's Black Diamond™ and Coral™.

As used herein, “horizontal” refers to a general direction along a primary surface of a substrate, and “vertical” is a direction generally orthogonal thereto. Furthermore, “vertical” and “horizontal” are generally perpendicular directions relative to one another independent of orientation of the substrate in three-dimensional space.

Using the sacrificial gate 400 and sidewall spacers 440 as an etch mask, exposed portions of the epitaxial layers are etched to create source/drain cavities 500 laterally adjacent to the sacrificial gate 400 and extending through the epitaxial stack. The etching may include an RIE process, for example.

After etching the epitaxial stack to form source/drain cavities 500, remaining portions of the epitaxial stack define fin structures 280 having a length and width. The fin structures 280 may have a length (L) measured orthogonal to the gate width (w) of 20 to 100 nm, e.g., 20, 30, 40, 50, 60, 70, 80 90 or 100 nm, and a width (W) measured parallel to the gate width (w) of 10 to 60 nm, e.g., 10, 12, 15, 20, 30, 40, 50 or 60 nm, including ranges between any of the foregoing values.

A fin structure 280 having a width (W) that is less than 30 nm may be used to form a nanowire device, whereas a fin structure 280 having a width (W) that is 30 nm or greater may be used to form a nanosheet device. In such devices, current will flow from a source region to a drain region through a channel region in a direction parallel to the gate width (w).

As described in greater detail herein, following removal of the high-germanium content silicon germanium epitaxial layers 211, 212, 213, and the optional removal of the low-germanium content silicon germanium epitaxial layers 221, 222, 223, 224, the portions of the silicon layers 231, 232 remaining within the fin structure 280 will form channel regions of a nanosheet or nanowire FET.

Referring still to FIG. 2, portions of the sacrificial layers 211, 212, 213, 221, 222, 223, 224 exposed within source/drain cavities 500 are recessed laterally beneath the sidewall spacers 440 using a selective isotropic etch, such as a hydrogen chloride (HQ-based wet etch or a wet mixture of acetic acid (CH₃COOH), hydrogen peroxide (H₂O₂) and hydrofluoric acid (HF), to form corresponding recessed regions. The selective etch removes SiGe, for example, without etching silicon.

The recess etch may result in remaining portions of the sacrificial layers 211, 212, 213, 221, 222, 223, 224 having a substantially constant width, which may be equal to the width (w) of the sacrificial gate 400. In alternate embodiments, a width of the remaining portions of the sacrificial layers 211, 212, 213, 221, 222, 223, 224 may be less than or greater than the width (w) of the sacrificial gate 400.

Inner spacers 460 are formed to re-fill the recessed regions created by the recess etch of the sacrificial layers 211, 212, 213, 221, 222, 223, 224. Inner spacers 460 may be formed using a conformal ALD deposition process followed by an anisotropic etch back. In connection with various embodiments, inner spacers 460 include a material that is etch selective to silicon germanium, such as silicon nitride, although inner spacers 460 may include other etch selective dielectric materials. Inner spacers 460 provide shielding of later-formed source/drain regions during an etch step that is used to remove one or more of the SiGe layers.

In particular embodiments, an inner spacer 460 disposed at the lateral end of one or more recessed sacrificial silicon germanium layer is adapted to function as an etch barrier that protects an epitaxial source/drain region during removal of remaining portions of the sacrificial silicon germanium layers prior to the formation of the gate all around architecture.

Thereafter, referring still to FIG. 2, epitaxial source/drain regions 510, 520 are formed within source/drain cavities 500 by epitaxial growth from exposed portions of the silicon epitaxial layers 231, 232. The epitaxial source/drain region 510, 520 are electrically connected to semiconductor epitaxial layers 231, 232 within the channel regions of the structure, but isolated from the sacrificial SiGe layers 211, 212, 213, 221, 222, 223, 224 by inner spacers 460.

As will be appreciated by one skilled in the art, epitaxial source/drain regions 510 and epitaxial source/drain region 520 may be formed within PFET region 330 and NFET region 340, respectively, by alternately forming a block mask (not shown) over one device region and depositing, for example, silicon germanium (SiGe) source/drain regions 510 for PFET devices within PFET region 330 and silicon phosphorous (SiP) source/drain regions 520 for NFET devices within NFET region 340.

The sacrificial gate cap 430, in addition to functioning as a patterning layer for the sacrificial gate 400, is adapted to prevent epitaxial deposition onto the sacrificial gate conductor 420 during formation of source/drain regions.

Referring to FIG. 3, an interlayer dielectric 600 is formed over the source/drain regions 510, 520 and between exposed sidewalls of the sidewall spacers 440. The ILD layer 600 may be formed using a CVD process and may include a low dielectric constant material. For example, the ILD layer 600 may include an oxide such as SiO₂, borophosphosilicate glass (BPSG), TEOS, undoped silicate glass (USG), fluorinated silicate glass (FSG), high-density plasma (HDP) oxide, or plasma-enhanced TEOS (PETEOS).

A CMP process may be used to remove the ILD overburden and planarize a top surface of the structure. “Planarization” refers to a material removal process that employs at least mechanical forces, such as frictional media, to produce a substantially two-dimensional surface. A planarization process may include chemical mechanical polishing (CMP) or grinding. Chemical mechanical polishing (CMP) is a material removal process that uses both chemical reactions and mechanical forces to remove material and planarize a surface. In various embodiments, the sacrificial gate cap 430 may serve as a CMP etch stop.

Thereafter, referring still to FIG. 3, a selective etching step is used to remove the sacrificial gate 400, including sacrificial gate dielectric 410, sacrificial gate conductor 420 and sacrificial gate cap 430, to expose a top surface of the epitaxial stack. In embodiments where the sacrificial gate conductor 420 is amorphous silicon, the sacrificial gate conductor 420 can be etched and removed selectively with respect to silicon dioxide and silicon nitride using a wet etch chemistry including, for example, hot ammonia or TMAH. FIG. 3A is a transverse cross-sectional view of the structure of FIG. 3 through the epitaxial layers within the n-type device region 340 following removal of the sacrificial gate 400.

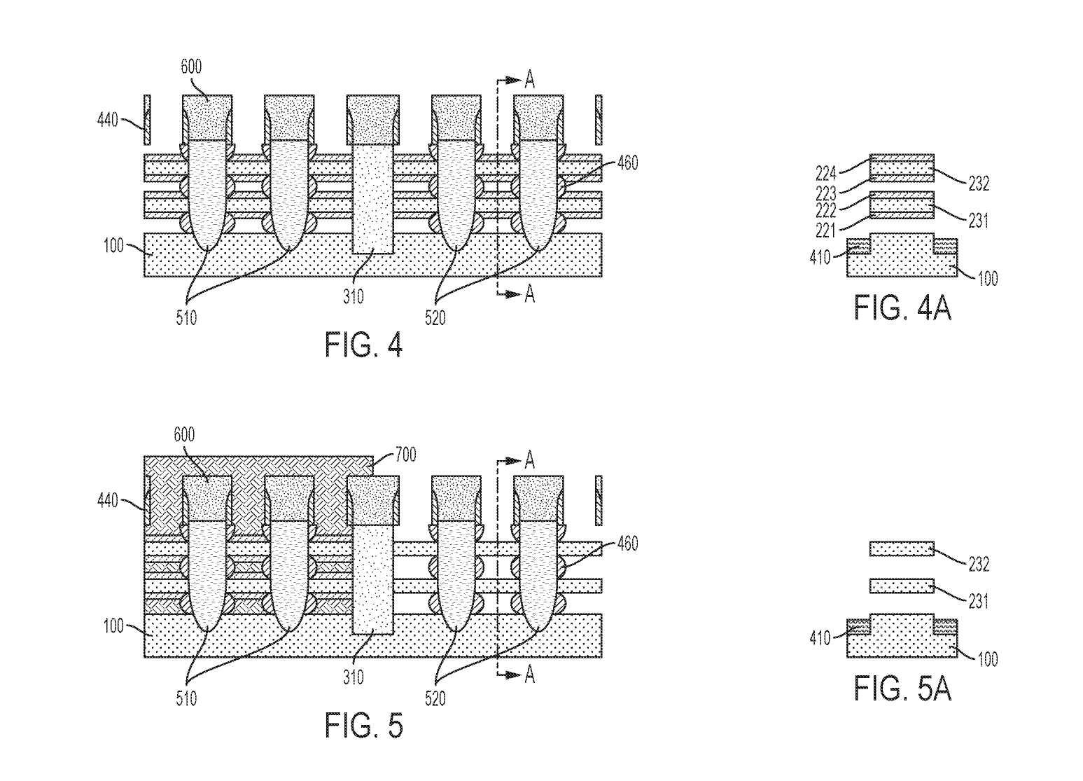

Referring to FIG. 4, subsequent to removal of the sacrificial gate 400, remaining portions of the high-germanium content silicon germanium epitaxial layers 211, 212, 213 are removed selective to the low-germanium content silicon germanium epitaxial layers 221, 222, 223, 224 and the silicon layers 231, 232. During removal of the high-germanium content silicon germanium epitaxial layers 211, 212, 213, inner spacers 460 and ILD layer 600 cooperate to protect the source/drain regions 510, 520, which may be formed from SiGe. A transverse cross-sectional view of the structure of FIG. 4 within the n-type device region 340 is depicted in FIG. 4A.

Suitable etch chemistries for etching the high-germanium content silicon germanium epitaxial layers selectively with respect to the low-germanium content silicon germanium epitaxial layers may include a HCl-based wet or vapor etch, or a wet etch including a mixture of ammonium hydroxide (NH₄OH), hydrogen peroxide (H₂O₂) and water, for example.

The terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

Turning to FIG. 5, a masking layer 700 is formed over the device topography and patterned in such a way as to cover p-type device region 330 and leave n-type device region 340 exposed. A further etching step is then used to remove the low-germanium content silicon germanium epitaxial layers 221, 222, 223, 224 from within the n-type device region 340 and expose silicon nanostructures 231, 232. The further etching step may include a wet etch using, for example, a mixture of ammonium hydroxide (NH₄OH), hydrogen peroxide (H₂O₂) and water, which can be sued to etch silicon germanium selective to silicon.

Revealed silicon nanostructures 231, 232 are shown schematically in the cross-sectional view of FIG. 5A. Within the p-type device region 330, the low-germanium content silicon germanium epitaxial layers 221, 222, 223, 224 remain disposed over the silicon nanostructures 231, 232.

The masking layer 700 is then removed from within the p-type device region 330, and gate dielectric and work function metal layers (collectively 800) are formed in succession over the nanostructures within each of the p-type and n-type device regions 330, 340. The masking layer 700, which may include a carbon-based spin-on layer, may be removed by ashing, for example. In certain embodiments, the gate dielectric layer is formed simultaneously within the p-type and n-type device regions 330, 340, followed by the simultaneous deposition of the work function metal layer(s) within the p-type and n-type device regions 330, 340.

The gate dielectric layer (not separately shown) can be formed using, for example, chemical vapor deposition (CVD), physical vapor deposition (PVD), molecular beam deposition (MBD), pulsed laser deposition (PLD), liquid source misted chemical deposition (LSMCD), atomic layer deposition (ALD), etc.

In certain embodiments, the gate dielectric layer includes a dielectric metal oxide having a dielectric constant that is greater than the dielectric constant of silicon dioxide. By way of example, the gate dielectric layer can have a dielectric constant greater than 4. In certain embodiments, the gate dielectric layer can have a dielectric constant greater than 8.

In accordance with certain embodiments, the gate dielectric material can include a material selected from hafnium oxide, zirconium oxide, tantalum oxide, titanium oxide, silicates of thereof, and alloys thereof. The thickness of the gate dielectric layer may be 1 nm to 6 nm, e.g., 1, 2, 4 or 6 nm, including ranges between any of the foregoing values.

As will be appreciated, within the p-type device region 330, the gate dielectric is formed over silicon nanostructures 231, 232, i.e., directly over low-germanium content silicon germanium epitaxial layers 221, 222, 223, 224, while within the n-type device region 340, the gate dielectric is formed directly over silicon nanostructures 231, 232.

Following deposition of the gate dielectric, a work function metal layer is deposited to fill remaining portions of the opening surrounding the nanostructures. In certain embodiments, prior to formation of the gate dielectric, the spacing between adjacent silicon nanostructures may be 8 to 15 nm, e.g., 8, 10, 12 or 15 nm, including ranges between any of the foregoing values.

In an illustrative example, a work function material layer can be deposited directly on the gate dielectric layer. The work function material layer can include an elemental composition or a metallic compound, which includes a metal and a non-metal element. The metallic compound can be selected from metallic nitrides, tantalum carbide, and hafnium-silicon alloys, for example. Exemplary metallic nitrides include titanium nitride, tantalum nitride, tungsten nitride, and combinations thereof.

The work function material layer can be formed by physical vapor deposition, chemical vapor deposition, or atomic layer deposition (ALD). The thickness of the work function material layer is pre-set by the dimensions of the sacrificial SiGe layer(s), but typically ranges from 1 nm to 15 nm, e.g., 1, 2, 4, 8, 10, 12 or 15 nm, including ranges between any of the foregoing values. An exemplary work function metal stack includes a first layer of titanium nitride, a layer of titanium aluminum carbide, and a second layer of titanium nitride. In various embodiments, the same work function metal stack is deposited within both the p-type device region 330 and the n-type device region 340.

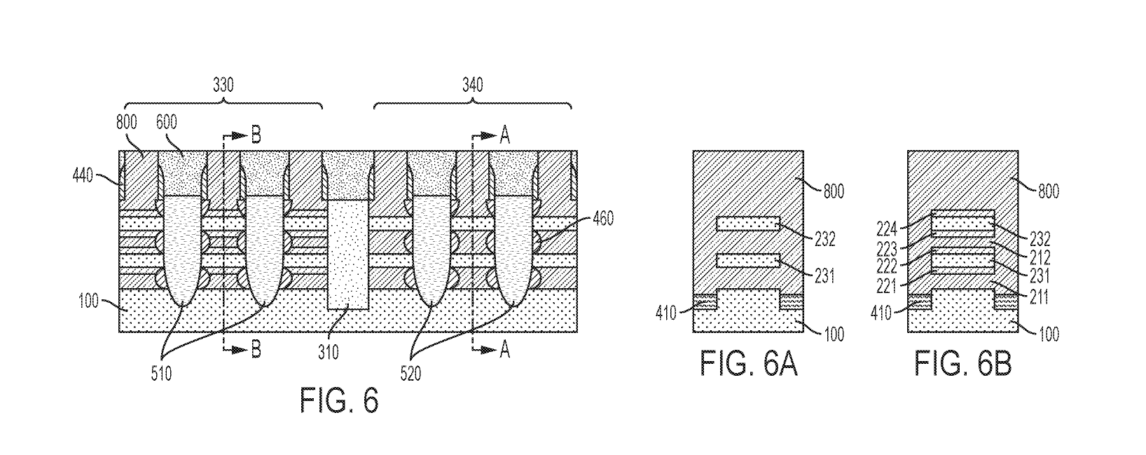

Referring to FIG. 6A and FIG. 6B, transverse cross-sectional views of the structure of FIG. 6 within the n-type device region 330 and the p-type device region 340, respectively, show the work function metal layer(s) formed directly over the low-germanium content silicon germanium epitaxial layers 221, 222, 223, 224 within the p-type device region 330, and directly over the silicon nanostructures 231, 232 within the n-type device region 340.

A conductive fill metal layer, such as a tungsten layer, may be used to fill remaining portions of the openings. As shown schematically in FIG. 6, FIG. 6A and FIG. 6B, a CMP process may be used to remove the work function metal overburden and planarize a top surface of the structure.

The work function of a material is an electrical property that describes the minimum energy required to remove an electron from the material. The work function layer of a functional gate, therefore, is a material layer that directly impacts the threshold voltage because it influences the amount of energy required for electrons to flow from the gate to a gate contact and thus influences the amount of energy available to attract charge carriers in a channel underlying the gate. In various embodiments described herein, providing different work function layer configurations can be useful in defining different threshold voltages.

According to various embodiments, a low-germanium content silicon germanium epitaxial layer is incorporated into the work function metal stack of a PFET device, and as is adapted to modify the PFET device work function. The embedded low-germanium content silicon germanium epitaxial layer enables the formation of PFET and NFET devices on a single substrate using a single, equivalent work function metal stack, e.g., TiN/TiAlN/TiN for both p-type and n-type devices.

A semiconductor structure disclosed herein may include one or more transistors, with each device including a source, drain, channel and gate. Moreover, it will be appreciated that although the various methods described herein relate to exemplary gate all around FET structures, such methods are not limited to a particular device architecture and may be used in conjunction with any other type of device or structure now known or later developed.

The methods described herein may be used, for example, for the fabrication of integrated circuit (IC) chips. The resulting integrated circuit chips can be distributed by the fabricator in raw wafer form, i.e., as a single wafer that has multiple unpackaged chips, as a bare die, or in packaged form. In the latter case, the chip may be mounted in a single chip package such as a plastic carrier, with leads that are affixed to a motherboard or other higher level carrier, or in a multichip package such as a ceramic carrier that has either or both surface interconnections or buried interconnections. In any case, the chip may then be integrated with other chips, discrete circuit elements, and/or other signal processing devices as part of either an intermediate product, such as a motherboard, or an end product. The end product can be any product that includes integrated circuit chips, ranging from toys and to advanced computer products having a central processor, a display, and a keyboard or other input device.

As used herein, the singular forms “a,” “an” and “the” include plural referents unless the context clearly dictates otherwise. Thus, for example, reference to a “silicon nanowire” includes examples having two or more such “silicon nanowires” unless the context clearly indicates otherwise.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred. Any recited single or multiple feature or aspect in any one claim can be combined or permuted with any other recited feature or aspect in any other claim or claims.

It will be understood that when an element such as a layer, region or substrate is referred to as being formed on, deposited on, or disposed “on” or “over” another element, it can be directly on the other element or intervening elements may also be present. In contrast, when an element is referred to as being “directly on” or “directly over” another element, no intervening elements are present.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to a layer that comprises silicon germanium include embodiments where a layer consists essentially of silicon germanium and embodiments where a layer consists of silicon germanium.

It will be apparent to those skilled in the art that various modifications and variations can be made to the present invention without departing from the spirit and scope of the invention. Since modifications, combinations, sub-combinations and variations of the disclosed embodiments incorporating the spirit and substance of the invention may occur to persons skilled in the art, the invention should be construed to include everything within the scope of the appended claims and their equivalents.

1. A method of fabricating a device, comprising:
forming a stack of epitaxial layers over a semiconductor substrate, wherein the stack comprises, from bottom to top, a first layer of high-germanium content silicon germanium, a first layer of low-germanium content silicon germanium, a first layer of silicon, a second layer of low-germanium content silicon germanium and a second layer of high-germanium content silicon germanium;
patterning the stack to form a first fin within a first device region and a second fin within a second device region;
removing the first layer of high-germanium content silicon germanium and the second layer of high-germanium content silicon germanium from within the first device region, wherein at least part of each of the first layer of low-germanium content silicon germanium and the second layer of low-germanium content silicon germanium remains disposed over the first layer of silicon in the first device region;
removing the first layer of high-germanium content silicon germanium, the second layer of high-germanium content silicon germanium, the first layer of low-germanium content silicon germanium, and the second layer of low-germanium content silicon germanium from within the second device region; and
forming a work function metal layer within the first and second device regions, wherein the work function metal layer is formed directly over the first and second low-germanium content silicon germanium layers within the first device region, and directly over the first layer of silicon within the second device region.

2. The method of claim 1, wherein the first and second layers of high-germanium content silicon germanium are removed simultaneously from within the first and second device region.

3. The method of claim 1, wherein the first and second layers of high-germanium content silicon germanium each have a thickness of 2 to 4 nm, the first and second layers of low-germanium content silicon germanium each have a thickness of 3 to 5 nm, and the first layer of silicon has a thickness of 4 to 6 nm.

4. The method of claim 1, wherein the first layer of high-germanium content silicon germanium is formed directly over the semiconductor substrate.

5. The method of claim 1, wherein a germanium content of the first and second layers of high-germanium content silicon germanium is at least 15 atomic percent greater than a germanium content of the first and second layers of low-germanium content silicon germanium.

6. The method of claim 1, further comprising forming a first sacrificial gate over the first fin and forming a second sacrificial gate over the second fin, and forming sidewall spacers over sidewalls of each sacrificial gate.

7. The method of claim 6, wherein patterning the stack comprises using the sacrificial gate and the sidewall spacers as an etch mask to etch exposed portions of the stack.

8. The method of claim 6, further comprising removing the silicon germanium layers from under the sidewall spacers to form recessed regions.

9. The method of claim 8, further comprising forming inner spacers within the recessed regions.

10. The method of claim 1, further comprising forming epitaxial source/drain regions laterally adjacent to each fin.

11. The method of claim 10, wherein forming the epitaxial source/drain regions comprises forming a silicon germanium (SiGe) epitaxial source/drain region within the first device region and forming a silicon phosphorus (SiP) epitaxial source/drain region within the second device region.

12. The method of claim 1, further comprises forming a masking layer over the first device region prior to removing the first layer of low-germanium content silicon germanium and the second layer of low-germanium content silicon germanium from within the second device region.

13. A method of fabricating a device, comprising:
forming a stack of epitaxial layers over a semiconductor substrate, wherein the stack comprises, from bottom to top, a first layer of high-germanium content silicon germanium formed directly over the semiconductor substrate, a first layer of low-germanium content silicon germanium, a first layer of silicon, a second layer of low-germanium content silicon germanium and a second layer of high-germanium content silicon germanium;
patterning the stack to form a first fin within a first device region and a second fin within a second device region;
removing the first layer of high-germanium content silicon germanium and the second layer of high-germanium content silicon germanium from within the first and second device regions;
forming a mask layer over the first device region;
removing the first layer of low-germanium content silicon germanium and the second layer of low-germanium content silicon germanium from within the second device region, wherein at least part of each of the first layer of low-germanium content silicon germanium and the second layer of low-germanium content silicon germanium remains disposed over the first layer of silicon in the first device region;
and
forming a work function metal layer within the first and second device regions, wherein the work function metal layer is formed directly over the first and second low-germanium content silicon germanium layers within the first device region, and directly over the first layer of silicon within the second device region.

14. The method of claim 13, further comprising forming a first sacrificial gate over the first fin and forming a second sacrificial gate over the second fin, and forming sidewall spacers over sidewalls of each sacrificial gate.

15. The method of claim 14, wherein patterning the stack comprises using the sacrificial gates and the sidewall spacers as an etch mask to etch exposed portions of the stack.

16. The method of claim 14, further comprising removing the silicon germanium layers from under the sidewall spacers to form recessed regions.

17. The method of claim 16, further comprising forming inners spacers within the recessed regions.

18. The method of claim 1, wherein forming the work function metal layer comprises forming a first layer of titanium nitride, forming a layer of titanium aluminum carbide over the first layer of titanium nitride, and forming a second layer of titanium nitride over the layer of titanium aluminum carbide.

19. The method of claim 1, wherein the first device region includes a PFET device and the second device region includes an NFET device.

20. The method of claim 13, wherein the first device region includes a PFET device and the second device region includes an NFET device.
